(19) United States
(12) Patent Application Publication
(10) Pub. No.: US 2005/0205891 A1
(43) Pub. Date: Sep. 22, 2005

(54) Distributed channel bipolar devices and architectures

(76) Inventor: James W. Holm-Kennedy, Honolulu, HI (US)

Correspondence Address: JAMES C. WRAY, 1493 CHAIN BRIDGE ROAD, SUITE 300, MCLEAN, VA, 22101, US

(21) Appl. No.: 11/083,109

(22) Filed: Mar. 18, 2005

Related U.S. Application Data
(60) Provisional application No. 60/554,610, filed on Mar. 18, 2004.
(60) Provisional application No. 60/554,612, filed on Mar. 18, 2004.
(60) Provisional application No. 60/554,616, filed on Mar. 18, 2004.

(51) Int. Cl. H01L 29/32; H01L 31/111

(52) U.S. Cl. 257/107; 257/212

(57) ABSTRACT

A new distributed channel bipolar device (DCBD) has a large channel of a selected shape formed in a surface of a substrate by doping or by influencing of a coating. The channel acts as a collector or emitter. Another emitter of a transistor is separated from the channel by a base of varying thickness. Drain collectors in contact with the channel provide distinct channel functions. A second transistor in the substrate has a base in contact with the channel. Electrical leads provide voltages. Current is controlled and varied by the channel and influencing chemicals.

This application claims the benefit of U.S. Provisional Application No. 60/554,610, filed Mar. 18, 2004, U.S. Provisional Application No. 60/554,612, filed Mar. 18, 2004, and U.S. Provisional Application No. 60/554,616, filed Mar. 18, 2004, which are hereby incorporated by reference in their entirety.

### BACKGROUND OF THE INVENTION

Biosensors have been and are being developed to detect, identify and quantify various biochemicals, ranging from proteins to toxins to RNA to c-DNA to oligos and to disease agents such as viruses, bacteria, spores and Prions. This list is by way of example, and is not intended to be complete. Some biosensors sense charge on the molecule. Many biochemicals carry a net charge. Electrophoresis methods and various blots exploit molecule net charge to affect physical separation of such molecules.

There is a significant problem with existing techniques such as electrophoresis and the various blots. These sensors are not specific in identifying the molecules in question unless significant post processing and labeling is employed. Further, a very large quantity of the tested biochemical is required for electrophoresis detection methodologies.

In many instances the number of molecules available for detection is very small and may be below the sensitivity threshold of the sensor, or may be problematic with respect to sensitivity. For example, some plasma proteins are of very low concentration. Toxins such as Botulinum toxin are notoriously hard to detect at lethal thresholds because of their very low lethal and sub-lethal, but still dangerous, concentrations. Mass spectroscopy requires a large number of molecules in order to achieve adequate detection sensitivity.

In the case of c-DNA and RNA sensing, the number of base pairs present may be low for adequate detection and determination of which one is trying to specifically identify. This is possible if, for example, only a few bacteria are present or the RNA is of low concentration because of function. Virus RNA may be of low density for samples monitoring air. Only a small portion of the RNA may provide the definitive identification signature. Overall this can lead to a relatively small amount of RNA actually involved in the definitive detection process, if only few bacterial or viruses are present.

In the case of proteins, the target molecule concentration may be very low in the sample. For example, with Prions (mad cow disease), if a fluid sample is taken from an animal's blood, the target protein concentration may be very low. With a rapid infection of humans, animals or plants with disease, the initial signature indicators may be present in only very small concentrations. For the very early stages of cancer, when one wishes to identify disease presence, definitive indicators may be present in only very small concentrations. An example includes the four or so proteins indicative of ovarian cancer. Where only small concentrations of target molecules are available, mass action effects can result in the bound target concentration being very low. A small percentage of the actual receptors, specific antibodies, available for bonding results in a very small detection signal, for example, as is the case of a lethal concentration of botulinum toxin. At the very earliest onset of disease, the density of indicative proteins, viruses, antibodies and bacteria may be very low, requiring putting a very high sensitivity burden on the sensing approach.

Sensors for the detection of target molecules using charge have been reported. The most commonly used to date are those using electrophoreses methods, such as the various blots. Semiconductor charge sensors have long been highly prized due to their compatibility with integrated circuits and attendant low cost manufacturing processes. An example is the ImmunoFET that uses a conventional MOSFET, absent a metal gate, and employing a reference electrode in solution.

Sensors sense a change in charge or chemical potential as a result of a chemical attachment to the gate region of the devices. Needs exist for sensitive sensors that can sense very low concentrations.

Contamination and pollution in water, air and foodstuff is a continuing threat to public health. Water contaminated with Pb, Hg, Dioxin, or other hazardous chemical substances is problematic. Air may be contaminated with hazardous chemicals, of which OSHA has a long list, either in the general environment, the home, the industrial workplace or the chemical factory. Food contamination is likewise problematic for public heath. The chemicals in question may be inorganic (such as Pb and Hg), organic (such as organic solvents) or biochemical such as viruses, bacteria, toxins and hazardous proteins.

Additional environmental threats arise from potential chemical use by terrorists. Such threats include the well-known toxins such as botulinum toxin and ricin, as well as many others. Another threat is that of explosives intentionally (such as bombs introduced by terrorists) or unintentionally (such as antipersonnel mines) found in some location.

There is a need for an electronic sensor that can detect such public health risk chemicals in water, air and foodstuffs. In general, such requirements include biosensors that may incorporate such specific chemical binding means as oligos, proteins and antibodies. These application sensors are discussed in a separate disclosure.

### SUMMARY OF THE INVENTION

This invention includes multiple applications CMOS compatible sensors, distributed channel bipolar devices (DCBDs), biosensors, force sensors, magnetic sensors and optical sensors. By making the active area of the sensor small and the depth of the doping and doping concentration small, the total number of charges in the channel is small. The devices include multiple terminal devices.

In basic semiconductor charge sensors, sensitivity is addressed by channel doping, geometrical considerations, active area, MOS structures, buried channel structures, channel thickness, channel dimensions, biases affecting channel charge, and biases affecting channel operating condition.

By making the active area of the sensor small and the depth of the doping and doping concentration small, the total number of charges in the channel is small. Thus, when charged molecules are attached to the active gate area and the molecular net charge's electric field terminates on the underlying channel, the number of free conducting charge carriers in the channel is modulated by precisely the number of charges on the gate. Thus, the fewer the charges in the channel, the larger the percentage change of the charge numbers in the channel and the larger the percentage change of the channel resistance under various operating conditions.

The devices include four terminal devices. Additional terminals may be added including multiple channels, multiple emitters, multiple bases and multiple gates. All of these have utility. The sensor has many chemical sensing applications as shown in Chart I.

Of particular interest is the sensing of biochemical molecules. By way of example, such molecules include, but are not limited to, those shown in Chart II.

The target molecules may include biomolecules from plants, animals and humans.

These and further and other objects and features of the invention are apparent in the disclosure, which includes the above and ongoing written specification, with the claims and the drawings.

### BRIEF DESCRIPTION OF THE DRAWINGS

FIG. 1 shows a lateral DCBD with a MOSFET channel.

FIG. 2A is a top view of a lateral DCBD with a channel.

FIG. 2B is a cross section of a buried channel DCBD.

FIG. 2C shows a gate geometry example.

FIG. 3 shows a basic configuration of a vertical DCBD.

### DETAILED DESCRIPTION OF THE PREFERRED EMBODIMENTS

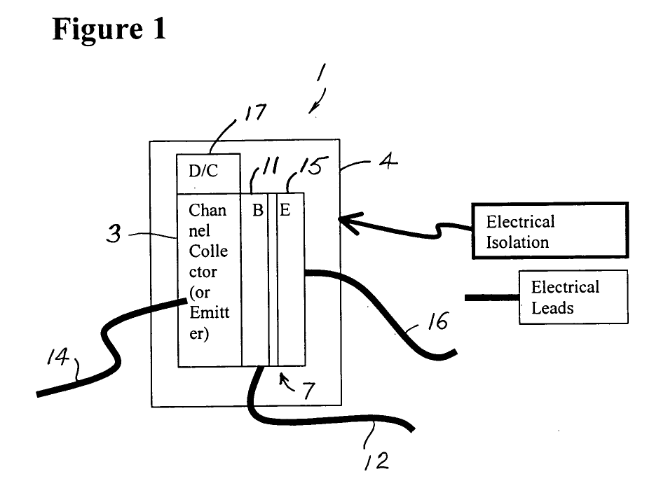

Basic Structures for the inventions include lateral distributed channel bipolar devices 1 (DCBDs), as shown in FIG. 1, which has a merged MOSFET and BJT, with the BJT being a lateral BJT. FIG. 1 shows a lateral DCBD 1 with a MOSFET channel 3 formed in substrate 4. In this example, the channel 3 is an n channel MOSFET 5 with an NPN integrated BJT 7. The n-MOSFET acts as a distributed channel or distributed collector. The channel 3 functions as a distributed collector, and the channel is controlled by a top gate bias and a back gate bias. The base 11 of the transistor is the substrate for the MOSFET. The devices may be an n channel with an NPN transistor or a p channel with a PNP transistor.

The BJT emitter 15 is an N+ (NPN) region laterally separated from the collecting channel by a base width. The MOSFET channel 3 can be the BJT collector or the BJT emitter. The MOSFET gate may be selectively shaped to provide a desired electrical function. The base 11 width may be inhomogeneous, with a varying width along the channel collector 3. The channel collector may be shaped to provide a pre-selected attractive function and to enhance certain useful electrical characteristics. Graded doping may be used. Mesa etching and other means may provide selective isolation of key portions of the device. Multiple emitters may be used. Multiple collectors may be used. Combination of p and n channel devices may be used to provide a complimentary or other device combination. Various characteristics are achieved by controlling the drain voltage, base current and collector to base voltage. It is noted that the transconductance threshold may be shifted by the back gate bias using the body effect. Electrical leads 12, 14, 16 are connected to the base 11, channel 3 and emitter 15, respectively. A drain/collector DC 17 is connected to the channel 3.

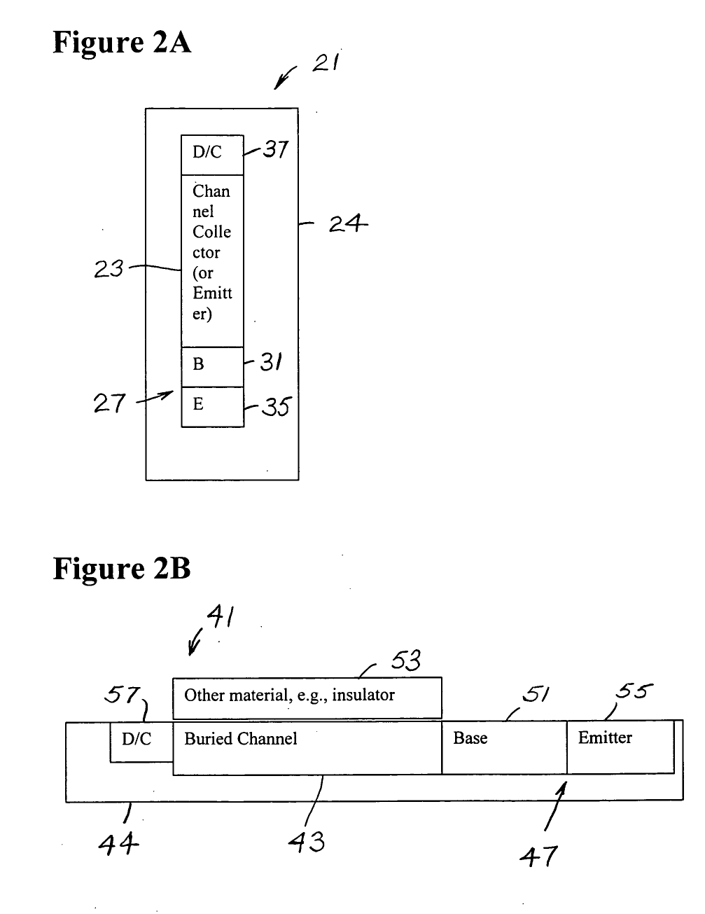

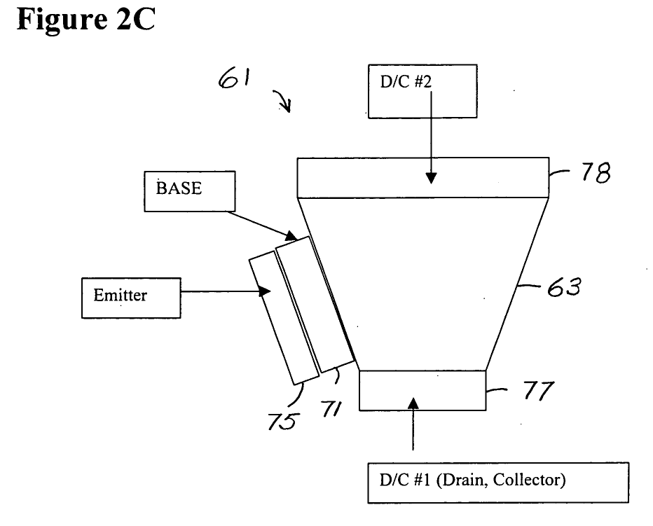

Lateral buried channel DCBDs, as shown in FIGS. 1 and 2A-C include a merged buried channel FET and BJT, with the BJT being a lateral BJT. There are two gates present. The first is a top gate that is a PN junction or a metal semiconductor junction. The channel functions as a distributed collector and the channel conductance is controlled by a top gate bias and a back gate bias. The base of the transistor is the substrate for the FET, which may be thought of as a JFET. The combination of the BJT and distributed collector JFET comprise a new device with novel electrical characteristics. The new devices are not JFET, MESFET, or BJT. The devices may comprise a buried n channel with an NPN transistor or a buried p channel with a PNP transistor.

FIG. 2A is a top view of a lateral DCBD 21 with a channel 23 in a substrate 24. The channel is formed with an FET 27. The FET may be a MOSFET, JFET, MESFET or other FET structure. An emitter 35 is spaced from the channel 23 by a base 31. A drain/collector DC 37 is connected to the other end of channel 23.

FIG. 2B is a cross section of a buried channel DCBD 41. Here, channel 43 the collecting channel or emitting channel in substrate 44 is a doped layer or heterostructure layer that self biases as a result of the collected or emitted current in the BJT. Base 51 is connected to the buried channel 43 and emitter 55 is connected to the base. The other material/insulator coating 53 on the buried channel 43 affects conductance of the channel.

FIG. 2C shows a gate geometry example in a DCBD 61. The channel collection regions 63, for both the MOS DCBD and the JFET DCBD, have a useful geometrical shape. The drain/collector 77, 78 contacts #1 and #2 provide multiple operational functionality.

The BJT 65 emitter 75 is a N+ (NPN) region laterally separated from the collecting channel by a base width 71. The JFET channel 63 can be the BJT collector or the BJT emitter. The JFET gate and channel 43 may be selectively shaped to provide a desired electrical function. The base 71 width may be inhomogeneous, with a varying width along the channel collector 43. The channel collector 43 may be shaped to provide a pre-selected attractive function and to enhance certain useful electrical characteristics. Graded doping may be used. Mesa etching and other means may provide selective isolation of key portions of the device. Various characteristics are achieved by controlling the drain voltage, base current and collector to base voltage. The transconductance threshold may be shifted by the back gate bias using the body effect.

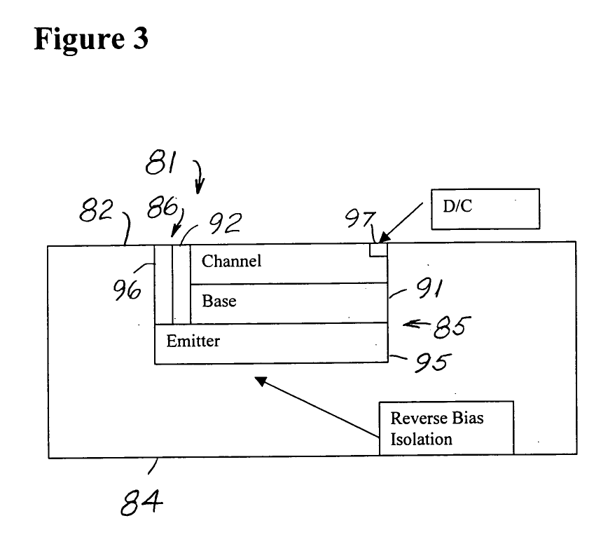

Vertical buried channel DCBDs 81, as shown in FIG. 3, include a merged buried channel FET 86 and BJT 85, with the BJT 85 being a vertical BJT with the collector or emitter 95 placed vertically with respect to the collecting channel 83 within substrate 84. FIG. 3 shows a basic configuration of a vertical DCBD 81. The collecting channel 83 may be located at the surface 82 above the BJT 87 structure or buried beneath the BJT structure. There are two gates present: a top gate and a bottom gate. The first is a top gate that is a PN junction or a metal semiconductor junction.

The channel 83 functions as a distributed collector or distributed emitter, and the channel conductance is controlled by a top gate bias and a back gate bias. The base 91 of the transistor 95 is located between the channel 83 FET and the BJT emitter. The combination of the BJT and distributed collector JFET comprises a new device with novel electrical characteristics. Said new devices are not a JFET, MESFET or BJT. The devices may comprise a buried n channel with an NPN transistor or a buried p channel with a PNP transistor. Drain/collector 97 is connected to channel 83.

The BJT emitter 95 is a N+ (NPN) region vertically separated from the collecting channel 83 by a base width 91. The JFET or MESFET channel can be the BJT collector or the BJT emitter. The JFET gate and channel may be selectively shaped to provide a desired electrical function. The channel collector may be shaped to provide a pre-selected attractive function and to enhance certain useful electrical characteristics. Graded doping may be used. Mesa etching and other means may provide selective isolation of key portions of the device. Various characteristics are achieved by controlling the drain voltage, base current and collector to base voltage. The transconductance threshold may be shifted by the back gate bias using the body effect.

Combined vertical and horizontal DCBDs include combinations of the devices described above, and also may include buried or convention FET channels. Not shown in figures are potential combinations of all embodiments.

Similar structures may integrate other DCBD structures such as MESFETs, HEMTs, and various hetero-structure devices.

It is noted that the buried channels may have conductivity inhomogeneities in all directions, said inhomogeneities being selected to provide a desirable electrical function. For example, a buried channel may be doped to have a higher conductivity at one end than the others.

While not adequate to describe the full usefulness of the DCBDS described herein, the devices may be thought of, in a limited way, as BJTs with distributed channel emitters or distributed channel collectors. Alternatively, the devices may be thought of as FETs with distributed BJT sources or distributed BJT drains.

Because of the uniqueness of the structures, especially the buried channel structures, it is noted that the channel may be biased to selectively affect the attraction, repulsion, binding or dissociation of target biochemical species. Further, groupings of such chemicals may occur. Molecules responding to the electric field, created by a biased gate region projecting an electric field into the surrounding medium containing the target species, place an electrostatic force on the dipoles and charged molecules. The dipoles may be permanent dipoles or induced dipoles, and the charges may be positive or negative.

The applications in biosensors apply to many types of biochemicals cells, bacteria, viruses, proteins, toxins and a diversity of systems.

While the invention has been described with reference to specific embodiments, modifications and variations of the invention may be constructed without departing from the scope of the invention, which is defined in the following claims.

CHART I

| Biosensors | Chemical Sensors | Magnetic Sensor |
|---|---|---|
| Force Sensors | Microfluidic Sensors | Reference |
| (accelerometers, | | Voltage Devices |
| microphones, flow sensors, | | |
| etc.) | | |
| Transconductance Device | Gain Device | Switch |
| Threshold Sensor | PhotoDetector | PhotoEmitter |
| Nuclear Radiation Detector | Modulator | Oscillator |
| Spatial Photo Detector | Spatial Biosensor | |

CHART II

| Nucleic Acids | Oligos | Viruses | Acids |
|---|---|---|---|
| | c- | Bacteria and it | Bases |
| | DNA | component parts | |
| | | such as epitopes, | |
| | | membranes, | |
| | | proteins, Etc. | |
| | RNA | Cells (all kinds) | Chemicals affecting cell |
| | | | function and body function |
| | DNA | Membranes | Isolelectric Molecules |
| | | | (conditions) |
| | Other | Receptors | pH and pH influenced |
| | | | molecules |
| Antibodies | | Proteins | Ions |
| Enzymes | | Hormones | Toxins |
| BioDefense | | Salts | Buffering Agents |
| Agents | | | |
| Pain Receptors | | Insecticides | Chemical Agents |
| Explosives | | Water Quality | Pb, Hg, and other |
| | | Monitoring | hazardous metals |
| Other | | Chemicals | |

1. A semiconductor sensor apparatus comprising a distributed channel bipolar device (DCBD) having a substrate and a distributed collector emitter channel in the substrate, a base in the substrate, a base in the substrate connected to the collector emitter channel, and an emitter in the substrate spaced from the channel by the base, a drain/collector connected to the channel in the base and electrical leads connected to the channel.

2. The apparatus of claim 1, wherein the base and the emitter for controlling current in the channel, base and emitter current according to influence on the channel by chemicals on a surface of the channel.

3. The apparatus of claim 2, wherein the drain/collector influences the current.

4. The apparatus of claim 1, wherein the channel functions as a distributed collector, and the channel is controlled by a top gate bias and a back gate bias.

5. The apparatus of claim 4, wherein the channel is an n channel MODFET with an NPN integrated BJT, and the n-MOSFET acts as a distributed channel or distributed collector.

6. The apparatus of claim 5, wherein the base of the transistor is the substrate for the MOSFET.

7. The apparatus of claim 5, wherein the BJT emitter is an N+ (NPN) region laterally separated from the collecting channel by a base width, and the MOSFET channel is the BJT collector or the BJT emitter.

8. The apparatus of claim 5, wherein the MOSFET channel is selectively shaped, and the base has an inhomogenous thickness varying along the channel collector.

9. The apparatus of claim 5, wherein the channel is constructed with graded doping in the substrate.

10. The apparatus of claim 5, wherein the channel is constructed with mesa etching in the substrate for providing selectively isolated portions of the channel.

11. The apparatus of claim 5, further comprising multiple emitters in the substrate separated from the channel by bases.

12. The apparatus of claim 5, further comprising multiple drain/collectors connected to the channel.

13. The apparatus of claim 12, wherein the channel is differentially shaped between the multiple drain/collectors, and the base and emitter are mounted on a portion of the channel between the multiple drain/collectors.

14. A method of semiconductor sensing comprising providing a distributed channel bipolar device (DCBD), providing a substrate and providing a distributed collector emitter channel in the substrate, a base in the substrate, providing a base in the substrate connecting the base to the collector emitter channel, and providing an emitter in the substrate, spacing the emitter from the channel by the base, providing a drain/collector, connecting the drain/collector to the channel in the base, and providing electrical leads connected to the channel.

15. The method of claim 14, wherein the base and the emitter for controlling current in the channel, base and emitter current according to influence on the channel by chemicals on a surface of the channel.

16. The method of claim 15, wherein the drain/collector influences the current.

17. The method of claim 14, wherein the channel functions as a distributed collector, and the channel is controlled by a top gate bias and a back gate bias.

18. The method of claim 14, wherein the method is used for chemical sensing, force sensing, photo detector sensing, magnetic sensing, temperature sensing, or sensing IC functional device electrical characteristics.
